(19) United States
(12) Patent Application Publication
(10) Pub. No.: US 2023/0352318 A1
(43) Pub. Date: Nov. 2, 2023

(54) Chemical Delivery System and Method for Eliminating Static Electricity in Chemical Delivery Pipelines

(71) Applicant: ChangXin Memory Technologies, Inc., Hefei City (CN)

(72) Inventors: Tsui-Han Chiu, Hefei City (CN); Qing Wang, Hefei City (CN); Hongxing Qin, Hefei City (CN); Yu Zhang, Hefei City (CN); Jianlu An, Hefei City (CN)

(21) Appl. No.: 17/431,150

(22) PCT Filed: Jun. 25, 2021
(86) PCT No.: PCT/CN2021/102295

§ 371 Date: Aug. 13, 2021

(30) Foreign Application Priority Data
Sep. 3, 2020 (CN) 202010915729.7

(51) Int. Cl. H01L 21/67; H05F 3/00

(52) U.S. Cl. CPC H01L 21/67017; H05F 3/00

(57) ABSTRACT

The application discloses a chemical delivery system and a method for eliminating static electricity in a chemical delivery pipeline, including: a chemical reagent delivery pipe, a liquid storage device and an aerosol generating device. The liquid storage device stores the aerosol generating solution. The input end and the output end of the aerosol generating device are respectively communicated with the liquid storage device and the chemical reagent delivery pipe. The aerosol generating solution in the liquid storage device enters the aerosol generating device. The aerosol generating device converts the aerosol generating solution from a liquid state to an aerosol state. The aerosol enters the chemical reagent delivery pipe and diffuses, then it adsorbs and eliminates the charged ions in the chemical reagent delivery pipeline, thereby preventing fire or explosion from electrostatic ions encountering flammable and explosive chemical reagents.

### CROSS REFERENCES TO RELATED APPLICATIONS

This application claims the benefit of priority to Chinese Patent Application CN 2020109157297 filed to CNIPA on 09:03/2020, entitled “Chemical Delivery System and Method for eliminating Static Electricity in Chemical Delivery Pipelines”, the contents of which are incorporated herein by reference in its entirety.

### TECHNICAL FIELD

This application relates to the technical field of semiconductor equipment, in particular, to a chemical delivery system and a method for eliminating static electricity in a chemical delivery pipeline.

### BACKGROUND

In the manufacturing process of semiconductor devices, the wafer is an indispensable basic component. In order to improve production efficiency, it is usually necessary to quickly dry the wafer after the wafer is cleaned. Due to its high volatility, high-concentration isopropanol can improve the drying efficiency of the wafer after the wafer is cleaned.

However, high-concentration isopropanol is highly corrosive, and the transmission of high-concentration isopropanol through stainless steel pipes is likely to cause corrosion to the stainless steel pipes and increase the risk of pipeline leakage. Therefore, most manufacturers will choose chemical reagent delivery pipelines made of polyvinylidene fluoride (PVDF) which has super tensile and temperature resistance to transport high-concentration isopropanol solution. However, the polyvinylidene fluoride material is a high-resistance medium, so the static electric charges accumulated in the chemical reagent delivery pipes cannot be dissipated in time, so the volatilization of high concentration isopropanol will form a flammable gas in the chemical reagent delivery pipes with concentrations up to 5000 ppm. In the chemical reagent transportation pipelines, static electricity may cause fire or explosion when encountering high concentration of isopropanol solution.

### SUMMARY

This application discloses a chemical delivery system and a method to eliminate static electricity in the chemical delivery pipelines of a chemical delivery system which carries high concentration isopropanol and risks fire or explosion.

One embodiment provides a chemical delivery system, including:
a chemical reagent delivery pipeline:
a liquid storage device for storing aerosol generating solution; and
an aerosol generating device respectively connected with the liquid storage device and the wall of the chemical reagent delivery pipeline, where the aerosol generating device is used for converting the aerosol generating solution from a liquid state to an aerosol state, and transporting the aerosol generating solution to inside the chemical reagent delivery pipeline to eliminate static electricity in the chemical reagent delivery pipeline.

In one embodiment, the aerosol generating device includes:
a venturi pipe having a first port and a second port, a diameter reducing part located between the first port and the second port, and a liquid inlet connected to the diameter reducing part, wherein the first port is provided with a gas interface, the second port is in connected with the chemical reagent delivery pipeline, herein the liquid inlet is connected with the liquid storage device, and the aerosol-generated liquid enters the diameter reducing part through the liquid inlet, wherein, from the first port and the second port to the diameter reducing part, the diameter of the venturi pipe is gradually reduced.

In one embodiment, it further includes a pressure control device connected to the gas inlet of the venturi pipe for controlling the pressure of the gas entering the gas inlet.

In one embodiment, the aerosol generating device includes a solution transport pipeline, the liquid storage device includes a liquid treatment device, and the liquid treatment device is disposed in the solution transport pipeline and located between the liquid storage device and the venturi pipe.

In one embodiment, it further comprises an aerosol delivery device, the aerosol delivery device is used to connect the second port of the venturi pipe to the wall of the chemical reagent delivery pipeline, and the aerosol delivery device is connected to the wall of the chemical reagent delivery pipe perpendicularly.

In an embodiment, the aerosol delivery device further includes a plurality of first connecting ports, and the plurality of first connecting ports are arranged at intervals along the extension direction of the chemical reagent delivery pipeline at the chemical reagent delivery pipeline. The output end of the aerosol generating device connects with the plurality of first connecting ports.

In one embodiment, it further includes a control device, electrically connected to the aerosol generating device, for controlling the aerosol generating device to generate the aerosol when the chemical reagent flows in the chemical reagent delivery pipeline, and make the solution change from a liquid state to an aerosol state.

The embodiment of the present application also provides a method for eliminating static electricity in a chemical transportation pipeline, including:
providing a aerosol generating device; and
controlling the aerosol generating device to deliver the aerosol to the chemical reagent delivery pipeline to eliminate static electricity in the chemical reagent delivery pipeline.

In one embodiment, the controlling the aerosol generating device to deliver the aerosol to the chemical reagent delivery pipeline to eliminate static electricity in the chemical reagent delivery pipe includes:
controlling the aerosol generating device to periodically generate the aerosol, and delivering the aerosol to the chemical reagent delivery pipeline to eliminate static electricity in the chemical reagent delivery pipeline.

In one embodiment, the pressure at which the aerosol generating device sprays the aerosol is controlled according to the flow rate of the chemical reagent in the chemical reagent delivery pipeline.

The chemical delivery system and the method for eliminating static electricity in the chemical delivery pipeline provided by the embodiments of the present application include a chemical reagent delivery pipe, a liquid storage device, and an aerosol generating device. The liquid storage device is used to store the aerosol generating solution. The input end and the output end of the aerosol generating device are respectively connected with the liquid storage device and the chemical reagent delivery pipe. The aerosol generating solution in the liquid storage device enters the aerosol generating device. The aerosol generating device converts the aerosol generating solution from a liquid state to an aerosol state. The aerosol enters the chemical reagent delivery pipeline and diffuses, and adsorbs and eliminates the charged ions in the chemical reagent delivery pipeline, so as to prevent the electrostatic charges from encountering flammable and explosive chemical reagents and causing fire or explosion.

### BRIEF DESCRIPTION OF THE DRAWINGS

To clearly describe the technical solutions in the embodiments of the present application or the existing art, the following drawings are used in the description. Obviously, the drawings in the following description are only referring to some embodiments of the application. For those of ordinary skill in the art, other drawings can be obtained based on these drawings without creative work.

FIG. 1 is a schematic structural diagram of a chemical delivery system provided by an embodiment of the application;

FIG. 2 is a schematic structural diagram of a chemical delivery system provided by another embodiment of the application; and

FIG. 3 is a schematic structural diagram of a chemical delivery system provided by another embodiment of the application.

### DESCRIPTION OF REFERENCE SIGNS

Chemical delivery system 10, liquid storage device 100, aerosol generating device 200, venturi pipe 210, gas interface 211, reducing part 212, nozzle 217, solution transport pipeline 220, on-off valve 213, pressure control device 214, pressure gauge 215, gas flow meter 216, first port 218, second port 219, liquid inlet 223, filter 221, liquid flow meter 222, static elimination pipeline system 20, chemical reagent delivery pipe 300, first connecting port 310, dispersion pipeline 400, transfer interface 410, second connecting port 420, dispersion branch pipe 430, and the vacuum pump 500, liquid processing device 600, aerosol delivery device 700, and control device 800.

### DETAILED DESCRIPTION OF THE PREFERRED EMBODIMENTS

In order to make the above objectives, features, and advantages of the present application more obvious and understandable, the specific implementation manners of the present application will be described in detail below with reference to the accompanying drawings. In the following description, many specific details are set forth in order to fully understand this application. However, this application can be implemented in many other ways different from those described herein, and those skilled in the art can make similar improvements without violating the connotation of this application. Therefore, this application is not limited by the specific embodiments disclosed below.

In the description of this application, it should be understood that the terms “center”, “longitudinal”, “transverse”, “length”, “width”, “thickness”, “upper”, “lower”, “front”, “Back”, “Left”, “Right”, “Vertical”, “Horizontal”, “Top”. “Bottom”, “Inner”, “Outer”, “Clockwise”, “Counterclockwise”, “Axial”. “Radial”, “Circumferential”, etc. indicate the orientation or positional relationship based on the orientation or positional relationship shown in the drawings. They are only for the convenience of describing the application and simplifying the description, and do not indicate or imply the device or The element must have a specific orientation, be constructed and operated in a specific orientation, and therefore cannot be understood as a limitation of the present application.

In addition, the terms “first” and “second” are only used for descriptive purposes, and cannot be understood as indicating or implying relative importance or implicitly indicating the number of indicated technical features. Therefore, the features defined with “first” and “second” may explicitly or implicitly include at least one of the features. In the description of the present application. “a plurality of” means at least two, such as two, three, etc., unless specifically defined otherwise.

In this application, unless otherwise clearly specified and limited, the terms “installed”, “connected”, “connected”, “fixed” and other terms should be understood in a broad sense, for example, it can be a fixed connection or a detachable connection. Or integrated; it can be mechanically connected or electrically connected; it can be directly connected or indirectly connected through an intermediary, it can be the internal connecting of two components or the interaction relationship between two components, unless otherwise specified. For those of ordinary skill in the art, the specific meanings of the above-mentioned terms in this application can be understood according to specific circumstances.

In this application, unless expressly stipulated and defined otherwise, the first feature “on” or “under” the second feature may be in direct contact with the first and second features, or the first and second features may be indirectly through an intermediary, contact. Moreover, the “above”, “above” and “above” of the first feature on the second feature may mean that the first feature is directly above or obliquely above the second feature, or it simply means that the level of the first feature is higher than the second feature. The first feature “below”, “below” and “below” the second feature can mean that the first feature is directly below or obliquely below the second feature, or it simply means that the level of the first feature is smaller than the second feature.

It should be noted that when an element is referred to as being “fixed to” or “disposed on” another element, it can be directly on the other element or a central element may also be present. When an element is considered to be “connected” to another element, it can be directly connected to the other element or an intermediate element may be present at the same time. The terms “vertical”, “horizontal”, “upper”, “lower”, “left”, “right” and similar expressions used herein are for illustrative purposes only, and do not mean the only implementation.

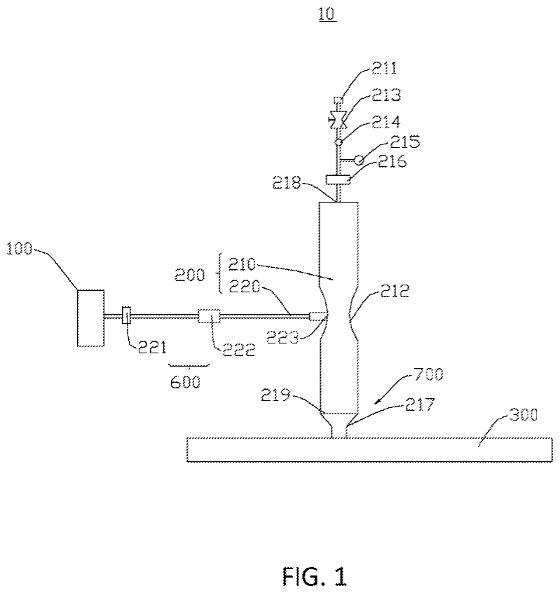

Referring to FIG. 1, an embodiment of the present application provides a chemical delivery system 10. The chemical delivery system 10 includes a chemical reagent delivery pipe 300, a liquid storage device 100 and an aerosol generating device 200. The aerosol generating device 200 is in connecting with the liquid storage device 100 and the chemical reagent delivery pipe 300 respectively. The liquid storage device 100 is used to store an aerosol generating solution. The aerosol generating device 200 is used for converting the aerosol generating solution from a liquid state to an aerosol state, and transporting the aerosol into the chemical reagent delivery pipe 300 to eliminate the static electricity from the chemical reagent delivery pipe 300.

The liquid storage device 100 may be a pressure vessel. The liquid storage device 100 may be made of polyester material or metal material, as long as the liquid storage device 100 is not easily corroded by the aerosol generating solution. The aerosol generating device 200 can atomize the aerosol generating solution to generate the aerosol. The liquid storage device 100 can deliver the aerosol to the aerosol generating device 200 through a power device. The aerosol device can also generate negative pressure to absorb the aerosol generating solution into the aerosol generating device 200. The aerosol generating device 200 can use the principle of fluid mechanics to vaporize the liquid aerosol generating solution into an aerosol state through the flow rate and pressure change of the aerosol generating solution. The aerosol can be sprayed from the output end of the aerosol generating device 200 into the chemical reagent delivery pipe 300. Since the aerosol can continuously diffuse in the chemical reagent delivery pipe 300, it can be combined with the charged ions in the chemical reagent delivery pipe 300, and can flow out of the chemical reagent along with the chemical reagent solution transport pipe 300. It can be understood that when the chemical delivery system 10 is applied to a semiconductor production line, the chemical reagent may be an isopropanol solution.

The chemical delivery system 10 provided by the embodiment of the present application includes a chemical reagent delivery pipe 300, a liquid storage device 100, and an aerosol generating device 200. The liquid storage device 100 is used to store an aerosol generating solution. The input and output ends of the aerosol generating device 200 are respectively connected to the liquid storage device 100 and the chemical reagent delivery pipe 300. The aerosol generating solution in the liquid storage device 100 enters the aerosol generating device 20K. The aerosol generating device 200 converts the aerosol generating solution from a liquid state to an aerosol state. The aerosol enters the chemical reagent delivery pipe 300 and diffuses, and adsorbs and eliminates the charged ions in the chemical reagent delivery pipe 300, so as to prevent electrostatic ions from encountering flammable and explosive isopropanol gas and causing fire or explode.

In one embodiment, the aerosol generating device includes a venturi pipe 210. The venturi pipe 210 has a first port 218 and a second port 219, a diameter reducing part 212 located between the first port 218 and the second port 219, and a liquid inlet connected to the diameter reducing part 212 to liquid inlet 223. The first port 218 is provided with a gas interface 211. The second port 219 is in connecting with the chemical reagent delivery pipe 300. The liquid inlet 223 is connecting with the liquid storage device 100. The aerosol generating solution enters the diameter reducing part 212 through the liquid inlet 223. Wherein, from the first port 218 and the second port 219 to the diameter reducing part 212, the diameter of the venturi pipe 210 decreases step by step.

The venturi pipe 210 may be ceramic, glass or polyester material. The gas interface 211 can be installed with a VCR connector. Through the gas interface 211, inert gas can be passed into the venturi pipe 210 through the first port 218 and the second port 219. In one embodiment, nitrogen can be introduced into the venturi pipe 210 through the gas interface 211. The diameter reducing part 212 may be located in the middle of the venturi pipe 210, that is, located between the first port 218 and the second port 219. It can be understood that the diameter of the venturi pipe 210 may be the same at both ends of the diameter reducing part 212. That is, the diameters of the first port 218 and the second port 219 may be the same. From the first port 218 to the second port 219 of the venturi pipe 210, the diameter of the venturi pipe 210 may gradually become smaller, and then gradually become larger. That is, in the diameter reducing part 212, the diameter of the venturi pipe 210 is the smallest. It can be understood that the diameter of the venturi pipe 210 gradually decreases from the two ends of the diameter reducing part 212 to the middle part of the diameter reducing part 212. The diameter of the venturi pipe 210 decreases step by step. The cross-sectional area of the venturi pipe 210 may decrease at the same rate of change, or it may decrease step by step at different rates of change.

The liquid storage device 100 can contain an aerosol generating solution. In an embodiment, the aerosol generating solution may be an inorganic salt solution. In one embodiment, the aerosol generating solution may be a sodium chloride solution. The solubility of the sodium chloride solution may range from 5% to 10%. The size of the aerosol particle size can be adjusted by adjusting the solubility of the sodium chloride solution. The liquid inlet 223 may be provided on the side wall of the smallest diameter part of the diameter reducing part 212. The diameter reducing part 212 connects with the liquid storage device 100 through the liquid inlet 223.

In an embodiment, the chemical delivery system further includes a solution delivery pipeline 220. The two ends of the solution transport pipeline 220 are respectively connected with the solution transport pipeline 220 and the venturi pipe 210. One end of the solution transport pipeline 220 may connect with the venturi pipe 210 through the liquid inlet 233. The connection between the solution transport pipeline 220 and the venturi pipe 210 may be the position where the diameter of the venturi pipe 210 is the smallest, that is, the solution transport pipeline 220 may be connected between the diameter reducing part 212 and the venturi pipe 210.

The gas can be introduced into the venturi pipe 210 through the gas interface 211. When the gas passes through the diameter-reducing part 212. As the diameter of the venturi pipe 210 becomes smaller, the flow speed of the gas increases, and the pressure at the diameter-reducing part 212 decreases accordingly. Therefore, the pressure in the solution transport pipeline 220 is stronger than the pressure at the diameter reducing part 212. That is, compared to the solution transport pipeline 220, a negative gas pressure is formed at the diameter reducing part 212 relative to pipeline 220. Under the action of negative pressure, the aerosol generating solution in the liquid storage device 100 is sucked into the venturi 210. When the pressure of the diameter reducing part 212 reaches a certain value, the aerosol generating solution can be sprayed from the second port 219 of the venturi pipe 210 in an aerosol state. The aerosol can be sprayed into the chemical reagent delivery pipe 300 through the second port 219, and adsorb and eliminate the charged ions in the chemical reagent delivery pipe 300, so as to prevent electrostatic ions from building up higher concentrations to induce tire or explosion due to high isopropanol solution gas.

In one embodiment, the chemical delivery system 10 further includes a pressure control device 214. The pressure control device 214 is connected to the gas interface 211 of the Venturi pipe 210. It is used to control the pressure of the gas entering the gas interface 211. In an embodiment, the pressure control device 214 may be a pressure regulating valve 214.

In an embodiment, the chemical delivery system 10 further includes an on-off valve 213, a pressure gauge 215, and a gas flow meter 216. The on-off valve 213, the pressure control device 214, the pressure gauge 215, and the gas flow meter 216 are installed in the venturi pipe 210. The on-off valve 213, the pressure regulating valve 214, the pressure gauge 215, and the gas flow meter 216 are located between the gas interface 211 and the diameter reducing part 212 in sequence. That is, in the direction toward the variable diameter part 212, the on-off valve 213, the pressure control device 214, the pressure gauge 215, and the gas flow meter 216 are sequentially arranged on the gas interface 211 and the reducing diameter part 212.

The on-off valve 213 can control the gas to enter the venturi 210. The pressure control device 214 can adjust the pressure of the gas injected into the venturi 210. The pressure control device 214 can be adjusted in time so that the end of the venturi pipe 210 away from the gas interface 211 sprays the aerosol. The pressure gauge 215 can display the pressure value in the venturi 210. The gas flow meter 216 can monitor the flow rate of the gas in the venturi pipe 210.

In one embodiment, the liquid storage device 100 includes a liquid processing device 600.

The liquid processing device 600 is installed in the solution transport pipeline 220 and located between the liquid storage device 100 and the venturi pipe 210. The liquid processing device 600 can monitor and control the flow rate, temperature, pressure and other parameters of the aerosol generating solution output from the liquid storage device 100. The liquid processing device 600 can also control whether to output the aerosol generating solution in the liquid storage device 100. In an embodiment, the liquid processing device 600 can also filter the aerosol generating solution in the liquid storage device 100.

In an embodiment, the liquid treatment device 600 includes a filter 221 and a liquid flow meter 222. The filter 221 and the liquid flow meter 222 are arranged in the solution transport pipe 220 and are sequentially located between the liquid storage device 100 and the venturi pipe 210. That is, the filter 221 is arranged closer to the liquid storage device 100. The filter 221 can filter impurities in the aerosol generating solution output from the liquid storage device 100 to prevent the impurities from entering the venturi pipe 210 and causing blockage. The liquid flow meter 222 can monitor the flow rate of the aerosol generating solution in the solution transport pipeline 220.

In an embodiment, the chemical delivery system 10 further includes an aerosol delivery device 700. The aerosol delivery device 700 is used to connect the second port 219 of the venturi pipe 210 to the wall of the chemical reagent delivery pipe 300, and the aerosol delivery device 700 and the chemical reagent delivery pipe 300 are connected to each other. The walls are connected vertically. The aerosol delivery device 700 can make the aerosol enter the chemical reagent delivery pipe 300 as uniformly as possible.

In an embodiment, the aerosol delivery device 700 may further include a spray head 217. The spray head 217 is disposed at the second port 219 of the venturi pipe 210. The diameter of the spray head 217 away from the second port 219 is the smallest, so the aerosol spray rate can be increased. In one embodiment, from the end of the spray head 217 close to the venturi pipe 210 to the end of the spray head 217 far away from the venturi pipe 210, the cross-sectional area of the spray head 217 can range from small to large. Therefore, when the aerosol enters the part of the spray head 217 with a larger cross-sectional area, the flow speed decreases and the pressure increases, which can cause the aerosol turbulence, thereby avoiding the aggregation of the aerosol particles.

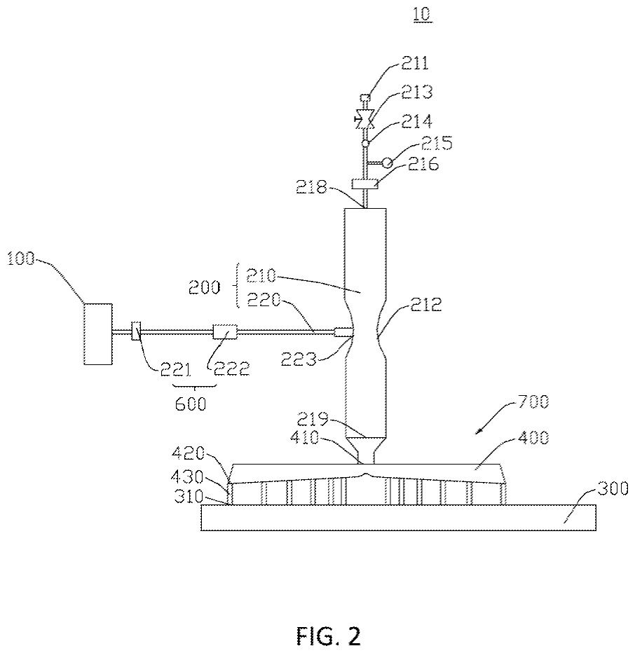

Referring to FIG. 2, in another embodiment, the aerosol delivery device 700 further includes a plurality of first connecting ports 310. The plurality of first connecting ports 310 are arranged at intervals at the chemical reagent delivery pipe 300 along the extending direction of the chemical reagent delivery pipe 300. The output end of the aerosol generating device 200 is connecting with the plurality of first connecting ports 310. That is, along the extending direction of the chemical reagent delivery pipe 300, the chemical reagent delivery pipe 300 is provided with a plurality of first connecting ports 310 at intervals. The output end of the aerosol generating device 200 is connecting with the plurality of first connecting ports 310. The plurality of first connecting ports 310 may be evenly spaced along the long axis of the chemical reagent delivery pipe 300. It can be understood that the aerosol output from the output end of the aerosol generating device 200 may enter the chemical reagent delivery pipe 300 through different first connecting ports 310 respectively. The aerosol can be uniformly diffused to a larger space in the chemical reagent delivery pipe 300. Therefore, the static electricity at different positions in the chemical reagent delivery pipe 300 can be absorbed and eliminated by the aerosol, thereby further reducing the charged ions in the chemical reagent delivery pipe 300.

In an embodiment, the aerosol delivery device 700 further includes a dispersion pipeline 400. The dispersion pipeline 400 is provided with a transfer interface 410. The transfer interface 410 is connecting with the output end of the aerosol generating device 200. Along the extension direction of the dispersion pipeline 400, the dispersion pipeline 400 is provided with a plurality of second connecting ports 420 at intervals. The plurality of first connecting ports 310 and the second connecting ports 420 are arranged in a one-to-one correspondence. The transfer interface 410 is arranged between any two adjacent second connecting ports 420. It can be understood that, similar to the arrangement of the first connecting port 310, the second connecting port 420 may also be uniformly disposed in the long axial direction of the dispersion pipeline 400. That is, the second connecting ports 420 may be provided at equal intervals in the axial direction of the dispersion pipeline 400. The first connection port and the second connection port may be arranged to connect with each other through a soft connection pipe or a hard connection pipe. The aerosol output from the output end of the aerosol generating device 200 can fill the dispersion pipeline 400 and then enter the plurality of first connecting ports 310 through the plurality of second connecting ports 420 respectively.

In one embodiment, the diameter of the dispersion pipeline 400 may be larger than the diameter of the chemical reagent delivery pipe 300, so that the aerosol can be fully diffused in the dispersion pipeline 400, so that the second connecting ports 420 passes the amount of the aerosol into the first connecting ports 310 as uniform as possible. The distribution of the aerosol in the chemical reagent delivery pipe 300 may be also more uniform.

In one embodiment, in the extension direction of the chemical reagent delivery pipe 300, the numbers of the second connecting ports 420 on both sides of the transfer port 410 are the same. That is, the transfer interface 410 is arranged in the middle of the plurality of second connecting ports 420. In an embodiment, the transfer interface 410 is also arranged in the middle of the chemical reagent delivery pipe 300. Therefore, the diffusion rate of the aerosol output from the transfer port 410 to the two ends of the dispersion pipeline 400 is relatively uniform. The amounts of the aerosol entering the plurality of second connecting ports 420 also tend to be the same.

In an embodiment, the dispersion pipeline 400 is disposed between the output end of the aerosol generating device 200 and the chemical reagent delivery pipe 300. The dispersion pipeline 400 is arranged in parallel to the chemical reagent delivery pipe 300. One of the plurality of first connecting ports 310 and one of the plurality of second connecting ports 420 are directly connected to each other in one by one, correspondence. The dispersion pipeline 400 and the chemical reagent delivery pipe 3M) are arranged to axis-aligned in the same plane. The aerosol output from the transfer interface 410 may enter the chemical reagent delivery pipe 300 through the dispersion pipeline 400. The dispersing pipe 400 and the chemical reagent delivery pipe 300 are arranged in parallel, so that the first connecting port 310 and the corresponding second connecting port 420 are directly facing each other, reducing the length of the pipe between the first connecting port 310 and the second connecting port 420. The pipeline lengths between each pair of the corresponding first connecting port 310 and the second connecting port 420 are the same. The rates of the aerosol entering the plurality of second connecting ports 420 are more uniform.

In one embodiment, the diameter of the dispersion pipeline 400 gradually increases from the transfer port 410 to both sides of the dispersion pipeline 400. The flow rate of the aerosol is related to the diameter of the dispersion pipeline 400. When the aerosol flows to the transfer port 410, the diameter of the dispersion pipeline 400 at the transfer port 410 is the smallest, the flow velocity of the aerosol at this position becomes larger than previous points, but the pressure becomes smaller than before. The diameter of the dispersion pipeline 400 from the transfer port 410 to the two ends of the pipeline 400 gradually increases, so the flow velocity of the aerosol to the two ends of the dispersion pipeline 400 will gradually decrease, but the pressure of the aerosol will gradually increase.

It is clear that at one of the second connecting ports 420, the greater the pressure of the aerosol is, the greater the rate of spraying into the connected first connecting port 310 will be. After the aerosol enters the chemical reagent delivery pipe 300, the second connecting port 420 closer to the transfer port 410 sprays the aerosol into the corresponding first connecting port 310, which generates larger diversions of aerosol flow. When the aerosol flows in the dispersion pipeline 400 to a position far away from the transfer port 410, the concentration of the aerosol becomes smaller. However, as the diameter of the dispersion pipeline 400 becomes larger, the flow velocity of the aerosol becomes smaller, and the pressure becomes larger. Therefore, the flow velocity of the aerosol sprayed from the second connecting port 420 is relatively increased. During the same time, the amount of the aerosol sprayed from the second connecting port 420 located farther away from the transfer port 410 is the same compared to the amount of the aerosol sprayed from the second connecting port 420 close to the transfer port 410. Therefore, it is possible to make the aerosol distribution in the chemical reagent delivery pipe 300 as uniform as possible.

In one embodiment, from the transfer port 410 to the two sides of the dispersion pipeline 400, the spaces from the next second connecting port 420 gradually become larger. That is, the second connecting ports 420 closer to the transfer port 410 have a higher density than the second connecting ports 420 farther away from the transfer port 410. As the density of the aerosol closer to the transfer port 410 is higher, and the flow rate in those areas is also faster. Therefore, the aerosol is not as easily injected from the second connection ports closer to the dispersion pipeline 400 as from those farther away. Therefore, by increasing the density of the second connection ports, the sprayed amount of the aerosol can be increased. At a position far away from the transfer port 410, the flow speed of the aerosol in the dispersion pipeline 400 becomes smaller, and the amount of the aerosol output by each second connecting port 420 there will be larger. By setting the distribution density of the second connecting ports 420 closer to the transfer port 410 to be larger, and setting the distribution density of the second connecting port 420 farther from the transfer port 410 to be smaller, the aerosol spray entering different positions in the chemical reagent delivery pipe 300 is more uniform.

In an embodiment, the aerosol delivery device 700 further includes a plurality of dispersing branch pipes 430. The plurality of dispersed branch pipes 430 are respectively connected between one of the first connecting ports 310 and one of the second connecting ports 420 in a one-to-one correspondence. That is, one dispersing branch pipe 430 can be connected between the correspondingly arranged first connecting port 310 and the second connecting port 420. The dispersing branch pipe 430 may be arranged vertically relative to the dispersing pipe 400 and the chemical reagent delivery pipe 300. The dispersing branch pipe 430 may be made of anti-corrosion materials such as polyester. The lengths between two adjacent ones of the plurality of dispersed branch pipes 430 may be the same. The aerosol can be delivered to different first connecting ports 310 through the dispersion branch pipes 430.

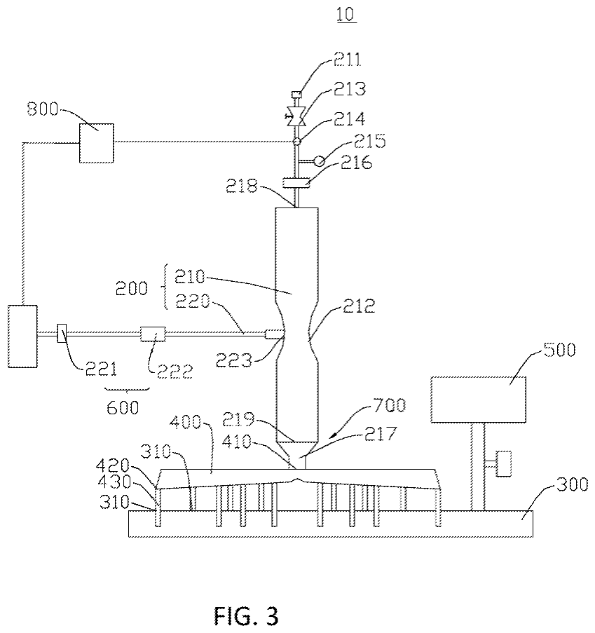

Referring to FIG. 3, in one embodiment, at least one of the dispersing branch pipes 430 extends into the chemical reagent delivery pipe 300 through the first connecting port 310, and is set up spaced away on the inner wall of the chemical reagent delivery pipe 300. Typically the inner wall of the chemical reagent delivery pipe 300 adsorbs charged ions easily. Due to the low density of the aerosol in the pipe, it is easy to float in the upper part of the chemical reagent delivery pipe 300. Therefore, the aerosol easily adsorbs the charged ions on the top surface of the inner wall of the chemical reagent delivery pipe 300. However, the isopropanol solution will flow at the bottom of the chemical reagent delivery pipe 300. Therefore, it is difficult for the aerosol to contact the charged ions at the bottom of the chemical reagent delivery pipe 300. At least one of the dispersion branch pipes 430 penetrates deep into the chemical reagent delivery pipe 300, that is, the outlet of the dispersion branch pipe 430 can extend to the bottom of the chemical reagent delivery pipe 300. The aerosol output from the dispersion branch pipe 430 can be directly sprayed to the bottom surface of the chemical reagent delivery pipe 300, so that the charged ions can be adsorbed at the bottom area of the chemical reagent delivery pipe 300. The outlet of the dispersing branch pipe 430 is spaced away from the inner wall of the chemical reagent delivery pipe 300, which can leave space for the aerosol output flow and avoid the aerosol ejection from the outlet of the dispersing branch pipe 430 strained by the inner wall. In one embodiment, a plurality of the dispersing branch pipes 430 alternately extend into the chemical reagent delivery pipe 300 along the extension direction of the chemical reagent delivery pipeline 430.

In one embodiment, along the flow direction of the isopropanol solution, a vacuum pump 500 is provided on the side of the chemical reagent delivery pipe 300 away from the output end of the aerosol generating device 200. Typically after the aerosol adsorbs the charged ions, the large aerosol particles that gradually fuse together may collide with each other. Under the action of gravity, the large aerosol particles may fall into the isopropanol solution and flow out with the isopropanol solution. When the isopropanol solution is a used waste solution, the particulate aerosol will be discharged into the liquid waste pool along with the isopropanol solution. Some of the aerosols that are not fused will still float in the chemical reagent delivery pipe 300. If the chemical reagent delivery pipe 300 transports the unused isopropanol solution, the aerosol can be eliminated by the vacuum pump 500, so the effect of the aerosol on the isopropanol solution can be minimized and the purity of the isopropanol solution can be improved.

It an embodiment, the chemical delivery system 10 further includes a control device 800. The control device 800 is electrically connected to the aerosol generating device 200. The control device 800 is used for controlling the aerosol generating device 200 to convert the aerosol generating solution from a liquid state to an aerosol state when the chemical solution flows in the chemical reagent delivery pipe 300. That is, the aerosol generating device 200 may have two states of pause and start/on. In fact, the isopropanol liquid waste is not always produced during the production process. That is, the isopropanol liquid waste of the chemical reagent delivery pipe 300 can be periodically generated. Therefore, when isopropanol liquid waste flows in the chemical reagent delivery pipe 300, the aerosol generating device 200 can be turned on to fill the chemical reagent delivery pipe 300 with the aerosol. The time for turning on the aerosol generating device 200 can be preset, as long as it is synchronized with the time when the isopropanol waste is discharged into the chemical reagent delivery pipe 300. In one embodiment, a sensing device can be used to sense whether there is the isopropanol liquid waste in the chemical reagent delivery pipe 300. When the isopropanol liquid waste is sensed, the control device 800 controls the aerosol generating device 200 to turn on. The control device 800 controls the aerosol generating device 200 to work periodically. Every time the aerosol generating device 200 is turned once, aerosol is sprayed into the chemical reagent delivery pipe 300 once, which saves the amount of aerosol while meeting the requirements of removing static electricity, meanwhile saves electricity.

The embodiment of the present application also provides a method for eliminating static electricity in a chemical transportation pipeline. The method includes steps:
S10, providing an aerosol generating device 200; and
S20: controlling the aerosol generating device 200 to deliver the aerosol to the chemical reagent delivery pipe 300 to eliminate static electricity in the chemical reagent delivery pipe 300.

The aerosol enters the chemical reagent delivery pipe 300 and diffuses, adsorbs and eliminates the charged ions in the chemical reagent delivery pipe 300, so as to prevent electrostatic ions from encountering flammable and explosive isopropanol gas and causing fire or explosion.

In an embodiment, the S20 includes:
S21, controlling the aerosol generating device 200 to periodically generate the aerosol;
S22: Transport the aerosol to the chemical reagent delivery pipe 300 to eliminate static electricity in the chemical reagent delivery pipe 300.

The aerosol generating device 200 periodically generates the aerosol, that is, the aerosol generating device 200 can periodically pause and work, and spray the aerosol to the chemical reagent delivery pipe 300 at regular intervals. Doing periodically can save the amount of aerosol thus reduce the production cost, as long as the requirement of removing static electricity is met. The working cycle of the aerosol generating device 200 can be synchronized with the cycle of discharging the isopropanol liquid waste into the chemical reagent delivery pipe 300.

In an embodiment, the pressure at which the aerosol generating device 200 sprays the aerosol is controlled according to the flow rate of the chemical reagent in the chemical reagent delivery pipe 300.

It can be understood that the flow of the chemical reagent in the chemical reagent delivery pipe 300 usually carries the flow of the aerosol. When the flow rate of the chemical reagent is too fast, the aerosol may be discharged from the chemical reagent delivery pipe 300 along with the chemical reagent before it has the effect of eliminating static electricity. If the pressure at which the aerosol is generated is not high enough, the aerosol will be discharged without touching the bottom of the chemical reagent delivery pipe 300. At this time, it is necessary to increase the spray intensity of the aerosol generating device 200 so that the aerosol contacts the bottom of the chemical reagent delivery pipe 300 as soon as possible. Conversely, when the flow rate of the chemical reagent is slow, the pressure at which the aerosol generating device 200 generates the aerosol can be reduced.

The experimental data proves that when the aerosol is not passed into the chemical reagent delivery pipe 300, the electrostatic voltage in the chemical reagent delivery pipe 300 can reach a range from 13 KV to 4.7 KV. After the aerosol is injected into the chemical reagent delivery pipe 300, the electrostatic voltage in the chemical reagent delivery pipe 300 drops below −1.0 KV, which can effectively control the electrostatic voltage to within a safe range. In addition, when the concentration of the isopropanol liquid waste exceeds 20%, the pipe material must be electrostatically conductive or electrostatic protection measures must be taken. The cost of the static conductive material or other static protection measures is relatively high, so it is valuable to use the static elimination pipeline system 10 effectively reduce costs and improve safety performance.

The technical features of the above-mentioned embodiments can be combined arbitrarily. In order to make the description concise, all possible combinations of the various technical features in the above-mentioned embodiments are not described. However, as long as there is no contradiction in the combination of these technical features, all should be considered as in the scope of this specification.

The above-mentioned embodiments only express a few implementation modes of the present application, and their description is relatively specific and detailed, but they should not be understood as a limitation on the scope of the invention patent. It should be pointed out that for those of ordinary skill in the an, without departing from the concept of this application, several modifications and improvements can be made, and these all fall within the protection scope of this application. Therefore, the scope of protection of the patent of this application shall be subject to the following claims.

1. A chemical delivery system, including:
a chemical reagent delivery pipe;
an aerosol generating device; and
a liquid storage device for storing aerosol generating solution;
wherein the aerosol generating device is respectively connected with the liquid storage device and a wall of the chemical reagent delivery pipe, wherein the aerosol generating device converts the aerosol generating solution from a liquid state to an aerosol state and transports the aerosol into the chemical reagent delivery pipe, and wherein the aerosol eliminates static electricity in the chemical reagent delivery pipe.

2. The chemical delivery system of claim 1, wherein the aerosol generating device comprises:
a venturi pipe including a first port and a second port, a diameter reducing part located between the first port and the second port, and a liquid inlet connected to the diameter reducing part;
wherein the first port is provided with a gas interface, the second port is connected with the chemical reagent delivery pipe, the liquid inlet is connected with the liquid storage device; wherein the aerosol generating solution enters the diameter reducing part through the liquid inlet, and wherein a diameter of the venturi pipe is gradually reduced from the first port and the second port to the diameter reducing part.

3. The chemical delivery system according to claim 2, further comprising a pressure control device connected to the gas interface of the venturi for controlling a pressure of the gas entering the gas interface.

4. The chemical supply system according to claim 2, wherein the aerosol generating device comprises a solution transport pipe, wherein the liquid storage device comprises a liquid processing device, and wherein the liquid processing device is arranged in the solution transport pipe between the liquid storage device and the venturi pipe.

5. The chemical supply system of claim 2, further comprising an aerosol delivery device for connecting the second port of the venturi pipe with a wall of the chemical reagent delivery pipe, and the aerosol delivery device is perpendicularly connected to the wall of the chemical reagent delivery pipe.

6. The chemical delivery system of claim 5, wherein the aerosol delivery device further comprises a plurality of first connecting ports, wherein the plurality of first connecting ports are arranged along an extension direction of the chemical reagent delivery pipe, wherein the chemical reagent delivery pipe is arranged at intervals, and wherein an output end of the aerosol generating device is connected with the plurality of first connecting ports.

7. The chemical delivery system of claim 1, further comprising a control device, electrically connected to the aerosol generating device, wherein the control device controls the aerosol when the chemical reagent flows in the chemical reagent delivery pipe, and wherein the aerosol generating device converts the aerosol generating solution from a liquid state to an aerosol state.

8. The chemical delivery system of claim 2, wherein the venturi pipe is made of ceramic, glass or polyester material.

9. The chemical delivery system of claim 2, wherein a VCR connector is installed at the gas interface; and wherein an inert gas is sent into the venturi pipe through the gas interface, the first port and the second port.

10. The chemical delivery system of claim 1, wherein the aerosol generating solution is an inorganic salt solution.

11. The chemical supply system of claim 3, wherein the pressure control device is a pressure regulating valve.

12. The chemical delivery system of claim 3, further comprising an on-off valve, a pressure gauge, and a gas flow meter; wherein the on-off valve, the pressure control device, the pressure gauge and the gas flow meter are arranged in the venturi pipe; and wherein the on-off valve, pressure regulating valve, the pressure gauge and the gas flow meter are sequentially located between the gas interface and the diameter reducing part.

13. A method for eliminating static electricity in a chemical reagent delivery pipe, comprising:
providing an aerosol generating device,
wherein the aerosol generating device is controlled to deliver aerosol to the chemical reagent delivery pipe to eliminate static electricity in the chemical reagent delivery pipe.

14. The method for eliminating static electricity in the chemical reagent delivery pipe according to claim 13, wherein said aerosol generating device being controlled to deliver aerosol to the chemical reagent delivery pipe comprises:
controlling the aerosol generating device to periodically generate the aerosol;
wherein the aerosol is delivered to the chemical reagent delivery pipe to eliminate static electricity in the chemical reagent delivery pipe.

15. The method for eliminating static electricity in the chemical reagent delivery pipe according to claim 14, further comprising:
controlling a pressure to spray the aerosol from the aerosol generating device, according to a flow speed of the chemical reagent in the chemical reagent delivery pipe.
